(19) United States
(12) Patent Application Publication
(10) Pub. No.: US 2024/0431214 A1
(43) Pub. Date: Dec. 26, 2024

(54) SEMICONDUCTOR DEVICE AND METHOD FOR FABRICATING THE SAME

(71) Applicant: UNITED MICROELECTRONICS CORP., Hsin-Chu City (TW)

(72) Inventor: Hui-Lin Wang, Taipei City (TW)

(73) Assignee: UNITED MICROELECTRONICS CORP., Hsin-Chu City (TW)

(21) Appl. No.: 18/224,050

(22) Filed: Jul. 19, 2023

(30) Foreign Application Priority Data
Jun. 20, 2023 (TW) 112123091

(51) Int. Cl. H10N 50/01; H01F 10/32; H10N 50/85

(52) U.S. Cl. CPC H10N 50/01; H01F 10/3254; H10N 50/85; H01F 10/3272; H10B 61/00

(57) ABSTRACT

A method for fabricating a semiconductor device includes the steps of first forming an inter-metal dielectric (IMD) layer on a substrate, forming a contact hole in the IMD layer, forming a barrier layer and a metal layer in the contact hole, planarizing the metal layer, forming a spin orbit torque (SOT) layer on the barrier layer and the metal layer, and then forming a magnetic tunneling junction (MTJ) on the SOT layer.

### BACKGROUND OF THE INVENTION

### 1. Field of the Invention

The invention relates to a semiconductor device and method for fabricating the same, and more particularly to a magnetoresistive random access memory (MRAM) and method for fabricating the same.

### 2. Description of the Prior Art

Magnetoresistance (MR) effect has been known as a kind of effect caused by altering the resistance of a material through variation of outside magnetic field. The physical definition of such effect is defined as a variation in resistance obtained by dividing a difference in resistance under no magnetic interference by the original resistance. Currently, MR effect has been successfully utilized in production of hard disks thereby having important commercial values. Moreover, the characterization of utilizing GMR materials to generate different resistance under different magnetized states could also be used to fabricate MRAM devices, which typically has the advantage of keeping stored data even when the device is not connected to an electrical source.

The aforementioned MR effect has also been used in magnetic field sensor areas including but not limited to for example electronic compass components used in global positioning system (GPS) of cellular phones for providing information regarding moving location to users. Currently, various magnetic field sensor technologies such as anisotropic magnetoresistance (AMR) sensors, GMR sensors, magnetic tunneling junction (MTJ) sensors have been widely developed in the market. Nevertheless, most of these products still pose numerous shortcomings such as high chip area, high cost, high power consumption, limited sensibility, and easily affected by temperature variation and how to come up with an improved device to resolve these issues has become an important task in this field.

### SUMMARY OF THE INVENTION

According to an embodiment of the present invention, a method for fabricating a semiconductor device includes the steps of first forming an inter-metal dielectric (IMD) layer on a substrate, forming a contact hole in the IMD layer, forming a barrier layer and a metal layer in the contact hole, planarizing the metal layer, forming a spin orbit torque (SOT) layer on the barrier layer and the metal layer, and then forming a magnetic tunneling junction (MTJ) on the SOT layer.

According to another aspect of the present invention, a semiconductor device includes an inter-metal dielectric (IMD) layer on a substrate, a metal interconnection in the IMD layer as the metal interconnection includes a barrier layer in the IMD layer and extended to a surface of the IMD layer and a metal layer on the barrier layer, a spin orbit torque (SOT) layer on the barrier layer and the metal layer, and a magnetic tunneling junction (MTJ) on the SOT layer.

According to yet another aspect of the present invention, a semiconductor device includes an inter-metal dielectric (IMD) layer on a substrate, a metal interconnection in the IMD layer, a spin orbit torque (SOT) layer on the metal interconnection, an interface layer on the SOT layer, and a magnetic tunneling junction (MTJ) on the interface layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-6 illustrate a method for fabricating a MRAM device according to an embodiment of the present invention.

FIGS. 7-14 illustrate a method for fabricating a MRAM device according to an embodiment of the present invention.

### DETAILED DESCRIPTION

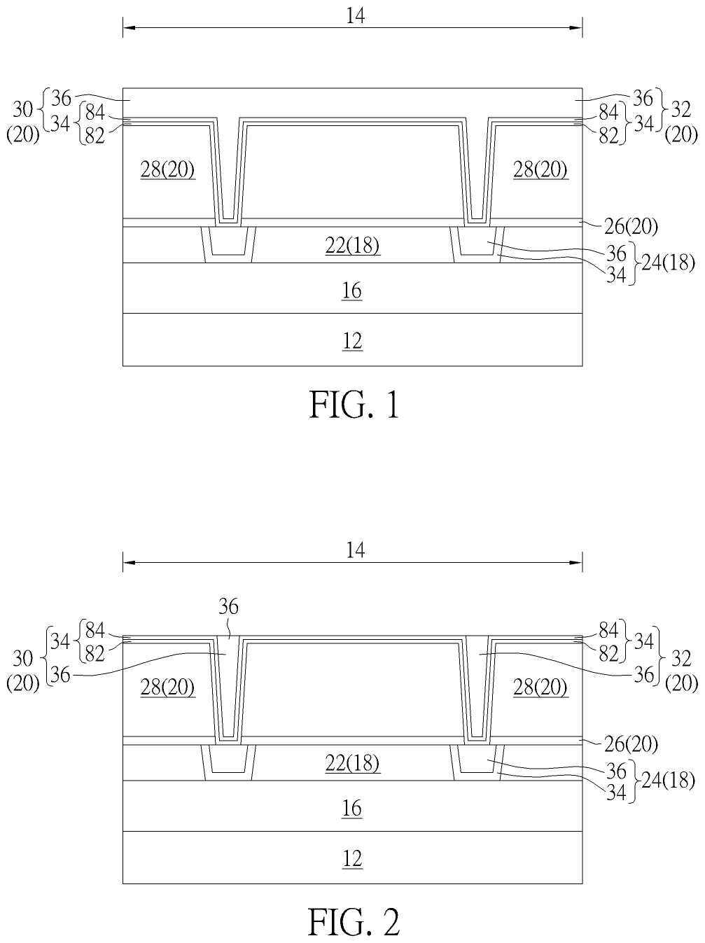

Referring to FIGS. 1-6, FIGS. 1-6 illustrate a method for fabricating a semiconductor device, or more specifically a MRAM device according to an embodiment of the present invention. As shown in FIG. 1, a substrate 12 made of semiconductor material is first provided, in which the semiconductor material could be selected from the group consisting of silicon (Si), germanium (Ge), Si—Ge compounds, silicon carbide (SiC), and gallium arsenide (GaAs), and a MRAM region 14 and a logic region (not shown) are defined on the substrate 12.

Active devices such as metal-oxide semiconductor (MOS) transistors, passive devices, conductive layers, and interlayer dielectric (ILD) layer 16 could also be formed on top of the substrate 12. More specifically, planar MOS transistors or non-planar (such as FinFETs) MOS transistors could be formed on the substrate 12, in which the MOS transistors could include transistor elements such as gate structures (for example metal gates) and source/drain region, spacer, epitaxial layer, and contact etch stop layer (CESL). The ILD layer 16 could be formed on the substrate 12 to cover the MOS transistors, and a plurality of contact plugs could be formed in the ILD layer 16 to electrically connect to the gate structure and/or source/drain region of MOS transistors. Since the fabrication of planar or non-planar transistors and ILD layer is well known to those skilled in the art, the details of which are not explained herein for the sake of brevity.

Next, metal interconnect structures 18, 20 are sequentially formed on the ILD layer 16 to electrically connect the aforementioned contact plugs, in which the metal interconnect structure 18 includes an inter-metal dielectric (IMD) layer 22 and metal interconnections 24 embedded in the IMD layer 22, and the metal interconnect structure 20 includes a stop layer 26, an IMD layer 28, and metal interconnections 30, 32 embedded in the stop layer 26 and the IMD layer 28.

In this embodiment, each of the metal interconnections 24 from the metal interconnect structure 18 preferably includes a trench conductor and each of the metal interconnections 30, 32 from the metal interconnect structure 20 includes a via conductor. Preferably, each of the metal interconnections 24, 30, 32 from the metal interconnect structures 18, 20 could be embedded within the IMD layers 22, 28 and/or stop layer 26 according to a single damascene process or dual damascene process. For instance, each of the metal interconnections 24, 30, 32 could further include a barrier layer 34 and a metal layer 36, in which the barrier layer 34 could be selected from the group consisting of titanium (Ti), titanium nitride (TiN), tantalum (Ta), and tantalum nitride (TaN) and the metal layer 36 could be selected from the group consisting of tungsten (W), copper (Cu), aluminum (Al), titanium aluminide (TiAl), and cobalt tungsten phosphide (CoWP). Since single damascene process and dual damascene process are well known to those skilled in the art, the details of which are not explained herein for the sake of brevity. In this embodiment, the metal layers 36 in the metal interconnections 24 are preferably made of copper, the metal layers 36 in the metal interconnections 30, 32 are preferably made of tungsten, the IMD layers 22, 28 are preferably made of silicon oxide or ultra low-k (ULK) dielectric layer, and the stop layers 26 is preferably made of nitrogen doped carbide (NDC), silicon nitride, silicon carbon nitride (SiCN), or combination thereof.

It should be noted that during the formation of the metal interconnections 30, 32 in the IMD layer 28 as shown in FIG. 1, a photo-etching process is first conducted to remove part of the IMD layer 28 and part of the stop layer 26 to form contact holes (not shown) exposing the metal interconnections 24 underneath, and then at least a barrier layer 34 and a metal layer 36 are deposited into the contact holes. Preferably, the barrier layer 34 is formed on the surface of the IMD layer 28 and sidewalls and bottom surface of the contact holes while the metal layer 36 is formed on the barrier layer 34 and filling the contact holes completely.

In this embodiment, the barrier layer 34 preferably includes a dual-layer structure, in which the lower barrier layer 82 closer and directly contacting the IMD layer 28 preferably includes Ti while the upper barrier layer 84 includes TiN. Nevertheless, according to other embodiment of the present invention, each of the barrier layers 82, 84 could all be selected from the group consisting of titanium (Ti), titanium nitride (TiN), tantalum (Ta), and tantalum nitride (TaN), which is also within the scope of the present invention.

Moreover, even though the barrier layer 34 of this embodiment pertains to be a dual-layer structure made of dual barrier layers 82, 84, according to other embodiment of the present invention the barrier layer 34 could also be a single-layered structure disposed between the IMD layer 28 and the metal layer 36, in which the single-layered barrier layer 34 could also be selected from the group consisting of titanium (Ti), titanium nitride (TiN), tantalum (Ta), and tantalum nitride (TaN). In other words, if the barrier layer 34 were to be a single-layered structure, the bottom surface of the barrier layer 34 made of TiN for instance would directly contacting the IMD layer 28 or metal interconnections 34 while the top surface of the same barrier layer 34 also made of TiN would directly contacting the metal layer 36 made of tungsten above.

Next, as shown in FIG. 2, a planarizing process such as a chemical mechanical polishing (CMP) process is conducted to remove part of the metal layer 36 until exposing the surface of the barrier layer 34. In other words, after removing part of the metal layer 36 and exposing the surface of the top surface of the barrier layer 34, the planarizing process preferably stops on the surface of the barrier layer 34 so that the top surface of the remaining metal layer 36 is even with the surface of the barrier layer 34 as the top surface of both the barrier layer 34 and metal layer 36 is higher than the top surface of the IMD layer 28. Since the planarizing process conducted at this stage preferably not removing any of the barrier layer 34, the barrier layer 34 would be disposed on the surface of the IMD layer 28 adjacent to two sides of the contact holes after conducting the planarizing process while the top surface metal layer 36 remained within the contact holes is slightly higher than the top surface of the IMD layer 28 and even with the top surface of the barrier layer 34.

Next, as shown in FIG. 3, after the planarizing process is conducted and before follow-up process is carried out, the top surface of the metal layer 36 contacting outside air is likely to be oxidized to form an interface layer 38 made of metal oxide. In this embodiment, since the metal layer 36 is preferably made of tungsten (W), the interface layer 38 formed by reacting the top surface of the metal layer 36 with outside oxygen gas is preferably made of tungsten oxide (WO).

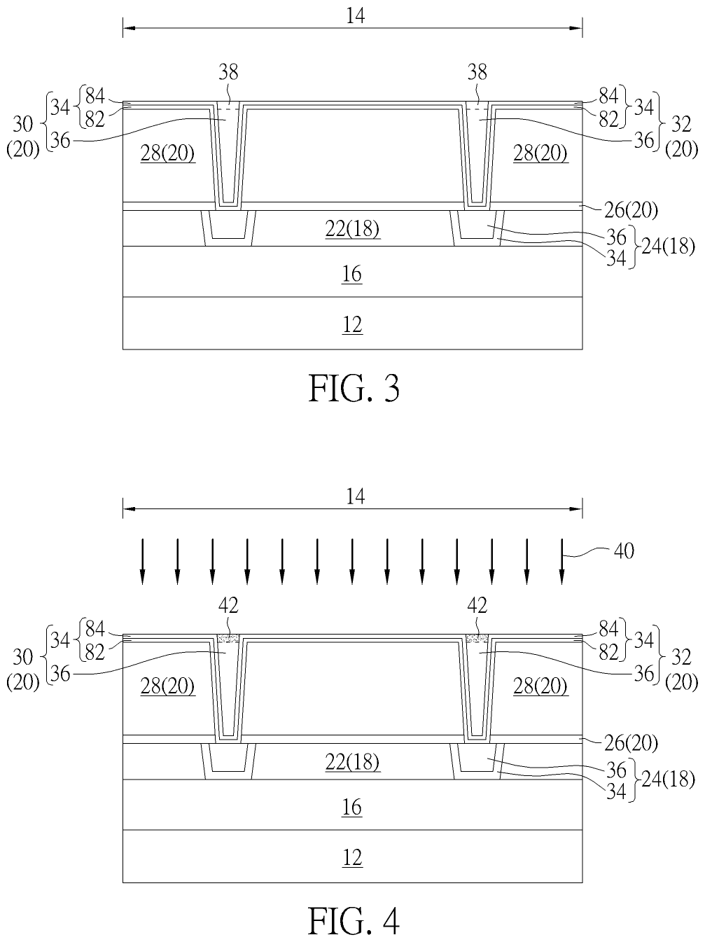

Next, as shown in FIG. 4, a doping process 40 is conducted by implanting nitrogen based dopants into the surface of the metal layer 36. This preferably transforms the interface layer 38 on surface of the metal layer 36 into another interface layer 42. In this embodiment, the nitrogen based dopants could include nitrogen gas (N₂) or ammonia (NH₃) and since the interface layer 38 formed through the aforementioned process preferably tungsten oxide, the new interface layer 42 formed by implanting nitrogen base dopants through the doping process 40 into the interface layer 38 preferably includes tungsten nitride (WN). In this embodiment, the top surface of the interface layer 42 is even with the top surface of the barrier layer 34 on two adjacent sides and the thickness of the interface layer 42 could be equal to a combined thickness of the two barrier layers 82, 84. Nevertheless, according to other embodiment of the present invention the thickness of the interface layer 42 could be less than, equal to, or greater than the sum of the two barrier layers 82, 84 or could also be less than, equal to, or greater than the thickness a single barrier layer 34 such as barrier layer 82 or 84, which are all within the scope of the present invention.

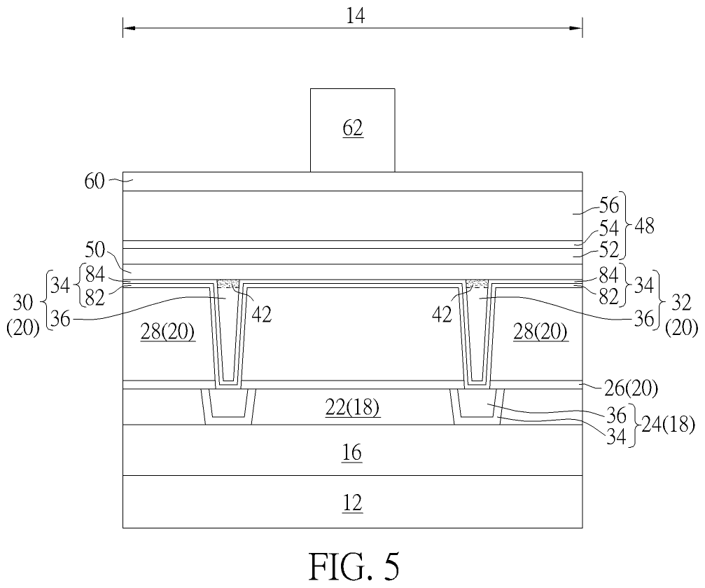

Next, as shown in FIG. 5, a spin orbit torque (SOT) layer 50 is formed on the surface of the barrier layer 34 and interface layer 42, a MTJ stack 48 is formed on the SOT layer 50, and then a cap layer 60 and a patterned mask 62 are formed on the MTJ stack 48.

In this embodiment, the formation of the MTJ stack 48 could be accomplished by sequentially depositing a free layer 52, a barrier layer 54, and a pinned layer 56 on the SOT layer 50. Preferably, the free layer 52 could be made of ferromagnetic material including but not limited to for example iron, cobalt, nickel, or alloys thereof such as cobalt-iron-boron (CoFeB), in which the magnetized direction of the free layer 52 could be altered freely depending on the influence of outside magnetic field. The barrier layer 54 could be made of insulating material including but not limited to for example oxides such as aluminum oxide (AlOₓ) or magnesium oxide (MgO). The pinned layer 56 could be made of antiferromagnetic (AFM) material including but not limited to for example ferromanganese (FeMn), platinum manganese (PtMn), iridium manganese (IrMn), nickel oxide (NiO), or combination thereof, in which the pinned layer 56 is formed to fix or limit the direction of magnetic moment of adjacent layers. It should be noted that since the present embodiment pertains to fabricating a SOT MRAM device, the free layer 52 is preferably disposed on the bottommost layer to contact the SOT layer 50 directly.

Preferably, the SOT layer 50 is serving as a channel for the MRAM device as the SOT layer 50 could include metals such as tantalum (Ta), tungsten (W), platinum (Pt), or hafnium (Hf) and/or topological insulator such as bismuth selenide (BiₓSe₁₋ₓ). The cap layer 60 preferably includes metal such as Ta and the hard mask 62 preferably includes conductive material such as metal or metal nitride, in which metal could include Ti whereas metal nitride could include TiN. Nevertheless, the cap layer 60 or hard mask 62 could all include conductive or dielectric material including but not limited to for example Ta, TaN, Ti, TiN, Pt, Cu, Au, Al, or combination thereof.

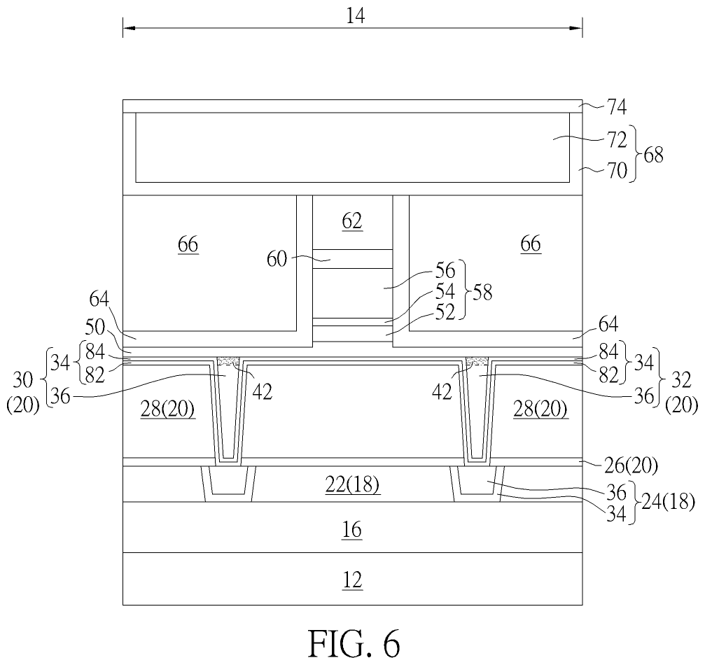

Next, as shown in FIG. 6, one or more etching process is conducted by using the patterned hard mask 62 as mask to remove part of the MTJ stack 48 and even part of the SOT layer 50 for forming a MTJ 58 on the SOT layer 50, and a cap layer 64 is formed on the surface of the hard mask 62, MTJ 58, and SOT layer 50. In this embodiment, the SOT layer 50 could be etched or not etched during the patterning of the MTJ stack 48 so that after the MTJ 58 is formed, the top surface of the SOT layer 50 directly under the MTJ 58 could be even with or slightly higher than the top surface of the SOT layer 50 adjacent two sides of the MTJ 58, which are all within the scope of the present invention. Preferably, the cap layer 64 is made of nitrogen doped carbide (NDC), silicon nitride (SiN), silicon carbon nitride (SiCN), or combination thereof and most preferably made of SiN.

Next, an IMD layer 66 is formed on the cap layer 60 and one or more photo-etching process is conducted to remove part of the IMD layer 66 and part of the cap layer 60 to form at least a contact hole (not shown) exposing the hard mask 62. Next, conductive materials are deposited into the contact hole and planarizing process such as CMP is conducted to form metal interconnection 68 connecting the hard mask 62 underneath, and another stop layer 74 is formed on the surface of the metal interconnection 68 thereafter. Similar to the aforementioned metal interconnections 24, the metal interconnection 68 could be embedded within the IMD layer 66 according to a single damascene process or dual damascene process. For instance, the metal interconnection 68 could further include a barrier layer 70 and a metal layer 72, in which the barrier layer 70 could be selected from the group consisting of titanium (Ti), titanium nitride (TiN), tantalum (Ta), and tantalum nitride (TaN) and the metal layer 72 could be selected from the group consisting of tungsten (W), copper (Cu), aluminum (Al), titanium aluminide (TiAl), and cobalt tungsten phosphide (CoWP).

In this embodiment, the IMD layer 66 preferably include an ultra low-k (ULK) dielectric layer including but not limited to for example porous material or silicon oxycarbide (SiOC) and the stop layer 74 preferably includes nitrogen doped carbide (NDC), silicon nitride (SiN), silicon carbon nitride (SiCN), or combination thereof and most preferably includes SiN. This completes the fabrication of a semiconductor device according to an embodiment of the present invention.

Referring again to FIG. 6, FIG. 6 further illustrates a structural view of a MRAM device according to an embodiment of the present invention. As shown in FIG. 6, the MRAM device includes an IMD layer 28 disposed on the substrate 12, metal interconnections 30, 32 in the IMD layer 28 as each of the metal interconnections 30, 32 includes a barrier layer 34 in the IMD layer 28 and extended to a surface of the IMD layer 28 and a metal layer 36 dispose don the barrier layer 34, a SOT layer 50 disposed on the metal interconnections 30, 32, and a MTJ 58 disposed on the SOT layer 50.

Specifically, the MRAM device also includes an interface layer 42 disposed on the surface of the metal layer 36, in which the top surface of the interface layer 42 is even with top surface of the barrier layer 34 while the top surface of both the interface layer 42 and the barrier layer 34 is higher than the top surface of the IMD layer 28 and the bottom surface of the SOT layer 50 preferably contacts the barrier layer 34 and interface layer 42 directly but not contacting the IMD layer 28. In this embodiment, the interface layer 42 and the barrier layer 34 are preferably made of different materials, in which the interface layer 42 preferably includes metal nitride such as WN while the barrier layer 34 includes metal nitride such as TiN, but not limited thereto.

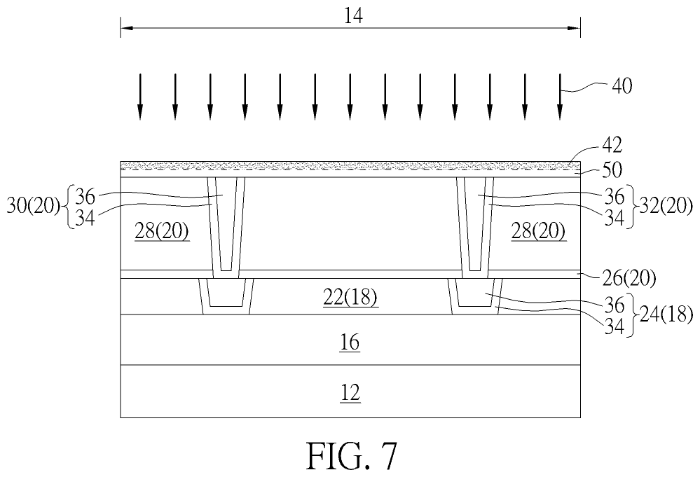

Referring to FIGS. 7-14, FIGS. 7-14 illustrate a method for fabricating a MRAM device according to an embodiment of the present invention. For simplicity purpose and further relating to the aforementioned embodiment, same elements in the following embodiment are labeled with same numberings from the previous embodiment. As shown in FIG. 7, a substrate 12 made of semiconductor material is first provided, in which the semiconductor material could be selected from the group consisting of silicon (Si), germanium (Ge), Si—Ge compounds, silicon carbide (SiC), and gallium arsenide (GaAs), and a MRAM region 14 and a logic region (not shown) are defined on the substrate 12.

Active devices such as metal-oxide semiconductor (MOS) transistors, passive devices, conductive layers, and interlayer dielectric (ILD) layer 16 could also be formed on top of the substrate 12. More specifically, planar MOS transistors or non-planar (such as FinFETs) MOS transistors could be formed on the substrate 12, in which the MOS transistors could include transistor elements such as gate structures (for example metal gates) and source/drain region, spacer, epitaxial layer, and contact etch stop layer (CESL). The ILD layer 16 could be formed on the substrate 12 to cover the MOS transistors, and a plurality of contact plugs could be formed in the ILD layer 16 to electrically connect to the gate structure and/or source/drain region of MOS transistors. Since the fabrication of planar or non-planar transistors and ILD layer is well known to those skilled in the art, the details of which are not explained herein for the sake of brevity.

Next, metal interconnect structures 18, 20 are sequentially formed on the ILD layer 16 to electrically connect the aforementioned contact plugs, in which the metal interconnect structure 18 includes an inter-metal dielectric (IMD) layer 22 and metal interconnections 24 embedded in the IMD layer 22, and the metal interconnect structure 20 includes a stop layer 26, an IMD layer 28, and metal interconnections 30, 32 embedded in the stop layer 26 and the IMD layer 28.

Similar to the aforementioned embodiment, each of the metal interconnections 24 from the metal interconnect structure 18 preferably includes a trench conductor and each of the metal interconnections 30, 32 from the metal interconnect structure 20 includes a via conductor. Preferably, each of the metal interconnections 24, 30, 32 from the metal interconnect structures 18, 20 could be embedded within the IMD layers 22, 28 and/or stop layer 26 according to a single damascene process or dual damascene process. For instance, each of the metal interconnections 24, 30, 32 could further include a barrier layer 34 and a metal layer 36, in which the barrier layer 34 could be selected from the group consisting of titanium (Ti), titanium nitride (TiN), tantalum (Ta), and tantalum nitride (TaN) and the metal layer 36 could be selected from the group consisting of tungsten (W), copper (Cu), aluminum (Al), titanium aluminide (TiAl), and cobalt tungsten phosphide (CoWP). Since single damascene process and dual damascene process are well known to those skilled in the art, the details of which are not explained herein for the sake of brevity. In this embodiment, the metal layers 36 in the metal interconnections 24 are preferably made of copper, the metal layers 36 in the metal interconnections 30, 32 are preferably made of tungsten, the IMD layers 22, 28 are preferably made of silicon oxide or ultra low-k (ULK) dielectric layer, and the stop layers 26 is preferably made of nitrogen doped carbide (NDC), silicon nitride, silicon carbon nitride (SiCN), or combination thereof.

Next, a spin orbit torque (SOT) layer 50 is formed on the surface of the metal interconnections 30, 32 and the IMD layer 28, in which the SOT layer 50 is serving as a channel for the MRAM device as the SOT layer 50 could include metals such as tantalum (Ta), tungsten (W), platinum (Pt), or hafnium (Hf) and/or topological insulator such as bismuth selenide (BiₓSe₁₋ₓ).

Next, a doping process 40 is conducted to implant nitrogen based or oxygen based dopants into the surface of the SOT layer 50 to transform part of the SOT layer 50 into an interface layer 42. Preferably, nitrogen based dopants could include nitrogen gas (N₂) or ammonia (NH₃) while oxygen based dopants could include oxygen gas and if the SOT layer 50 were made of tungsten (W) or platinum (Pt) for instance, the SOT layer 50 after being implanted with nitrogen or oxygen based dopants through the doping process 40 would be transformed into an interface layer 42 made of metal nitride or metal oxide such as tungsten nitride (WN), platinum nitride (PtN), tungsten oxide (WO), or platinum oxide (PtO). According to an embodiment of the present invention, the thickness of the interface layer 42 could be equal to, slightly less than, or slightly greater than the thickness of the remaining SOT layer 50. If the thickness of the interface layer 42 were to be less than or greater than the thickness of the SOT layer 50, the thickness of the interface layer 42 is preferably to be within 20% of the thickness of the SOT layer 50.

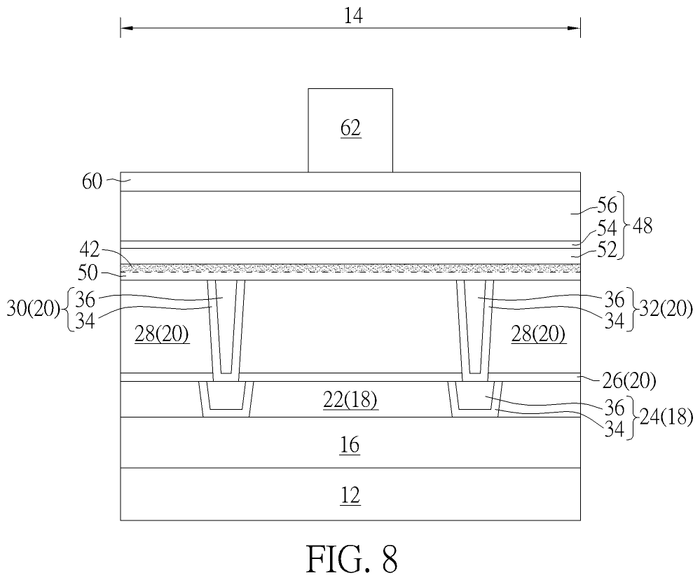

Next, as shown in FIG. 8, a MTJ stack 48 is formed on the SOT layer 50, and then a cap layer 60 and a patterned mask 62 are formed on the MTJ stack 48. Similar to the aforementioned embodiment, the formation of the MTJ stack 48 could be accomplished by sequentially depositing a free layer 52, a barrier layer 54, and a pinned layer 56 on the SOT layer 50. Preferably, the free layer 52 could be made of ferromagnetic material including but not limited to for example iron, cobalt, nickel, or alloys thereof such as cobalt-iron-boron (CoFeB), in which the magnetized direction of the free layer 52 could be altered freely depending on the influence of outside magnetic field. The barrier layer 54 could be made of insulating material including but not limited to for example oxides such as aluminum oxide (AlOₓ) or magnesium oxide (MgO). The pinned layer 56 could be made of antiferromagnetic (AFM) material including but not limited to for example ferromanganese (FeMn), platinum manganese (PtMn), iridium manganese (IrMn), nickel oxide (NiO), or combination thereof, in which the pinned layer 56 is formed to fix or limit the direction of magnetic moment of adjacent layers. It should be noted that since the present embodiment pertains to fabricating a SOT MRAM device, the free layer 52 is preferably disposed on the bottommost layer to contact the SOT layer 50 directly.

The cap layer 60 preferably includes metal such as Ta and the hard mask 62 preferably includes conductive material such as metal or metal nitride, in which metal could include Ti whereas metal nitride could include TiN. Nevertheless, the cap layer 60 or hard mask 62 could all include conductive or even dielectric material including but not limited to for example Ta, TaN, Ti, TiN, Pt, Cu, Au, Al, or combination thereof.

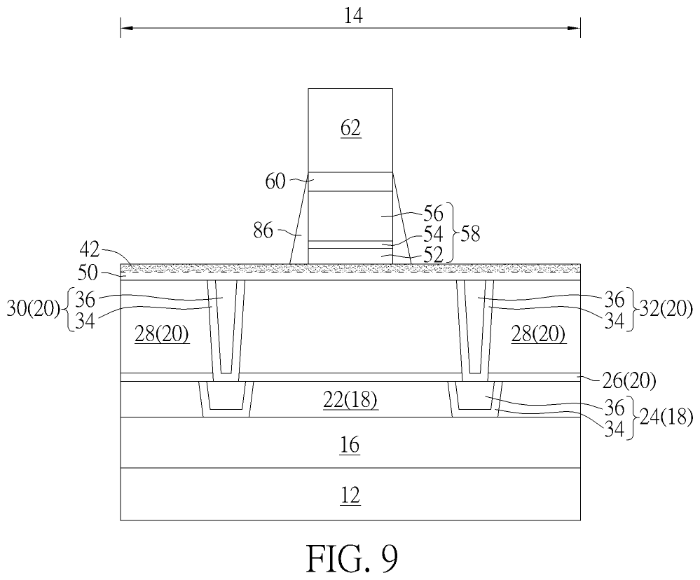

Next, as shown in FIG. 9, an etching process such as an inductively coupled plasma reactive ion etching (ICP-RIE) process is conducted by using the patterned hard mask 62 as mask to remove part of the cap layer 60 and part of the MTJ stack 48 for forming a MTJ 58 and at the same time forming a metallic byproduct 86 adjacent to the MTJ 58. In this embodiment, the ICP-RIE process conducted at this stage could be accomplished by using a base gas such as CFH or CHOH, but not limited thereto.

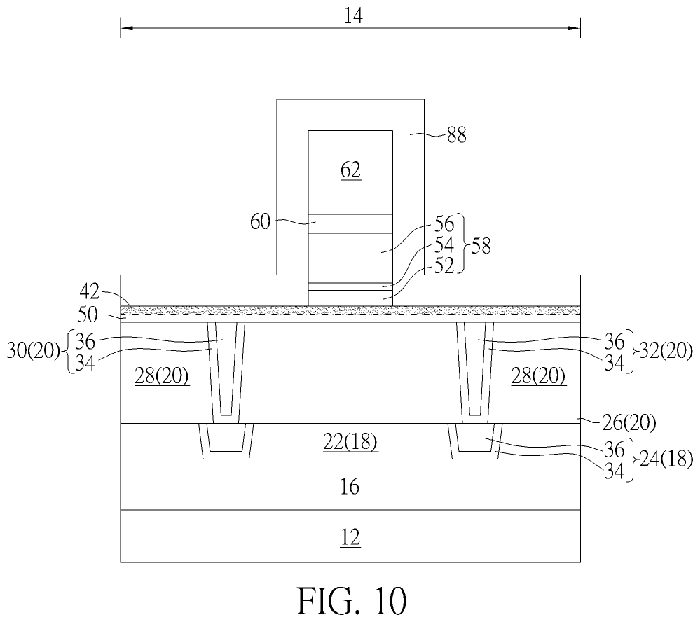

Next, as shown in FIG. 10, step (a) could be carried out by performing an oxidation process to transform the metallic byproduct 86 into an oxidized product 88. It should be noted that the oxidation process conducted at this stage could include an in-situ oxidation process, which could be accomplished by using N₂O to transform the metallic byproduct 86 into an oxidized byproduct 88. Structurally, the thickness of the oxidized byproduct 88 formed at this stage is slightly higher than the thickness of the metallic byproduct 86 formed in FIG. 9 and the oxidized byproduct 88 is disposed not only on sidewalls of the MTJ 58, sidewalls of the cap layer 60, and sidewalls of the hard mask 62 but also on the top surface of the hard mask 62 and the surface of interface layer 42 adjacent to two sides of the MTJ 58.

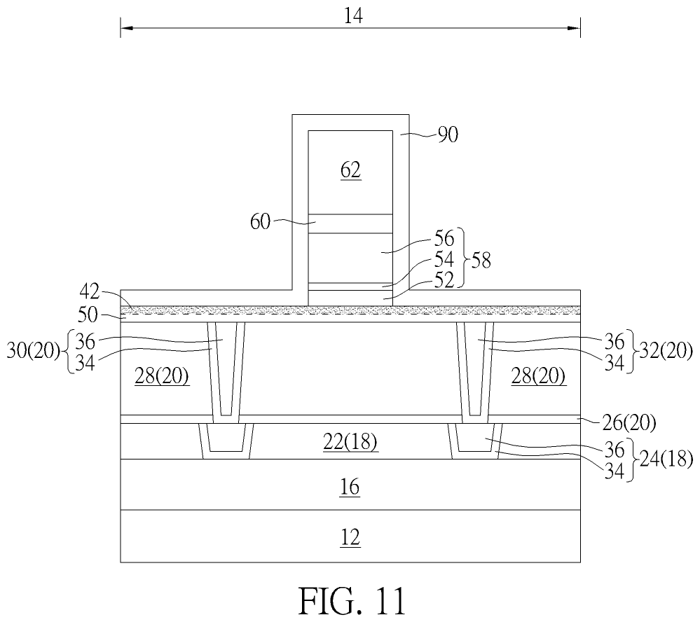

Next, as shown in FIG. 11, step (b) is conducted by performing an etching process to transform the oxidized product 88 into a damaged layer 90. Specifically, the etching process conducted at this stage includes an ICP-RIE process, which preferably uses a base gas content such as hydrogen gas (H₂) to transform the oxidized byproduct 88 into a damaged layer 90 including hydrogen atoms. Structurally, the thickness of the damaged layer 90 could be slightly lower than the thickness of the oxidized byproduct 88 formed in the previous stage.

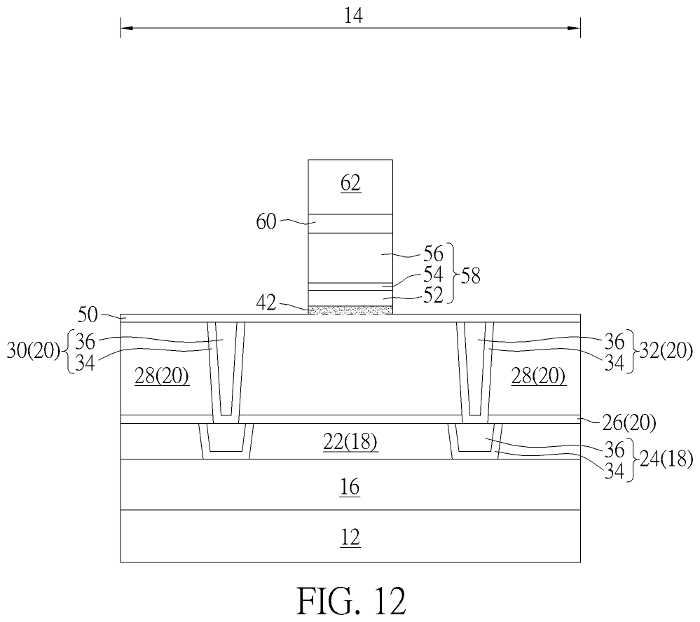

Next, as shown in FIG. 12, step (c) is conducted by performing an etching process to remove the damaged layer 88. Specifically, the etching process conducted at this stage includes an ICP-RIE process, which preferably uses a base gas containing argon (Ar) to remove the damaged layer 90 completely. It should be noted that when the ICP-RIE process is conducted to remove the damaged layer 90, part of the interface layer 42 adjacent to two sides of the MTJ 58 could also be removed at the same time to expose the surface of the SOT layer 50 underneath.

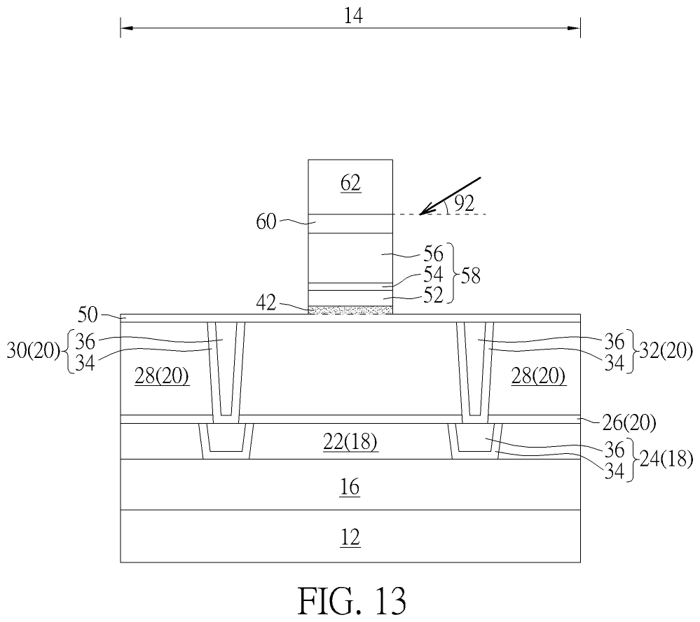

Next, as shown in FIG. 13, step (d) is conducted by performing an etching process to trim the MTJ 58. Preferably, the etching process conducted at this stage includes an ion beam etching (IBE) process and the etching process is accomplished by using low energy at angle 92 to trim the sidewalls of the MTJ 58.

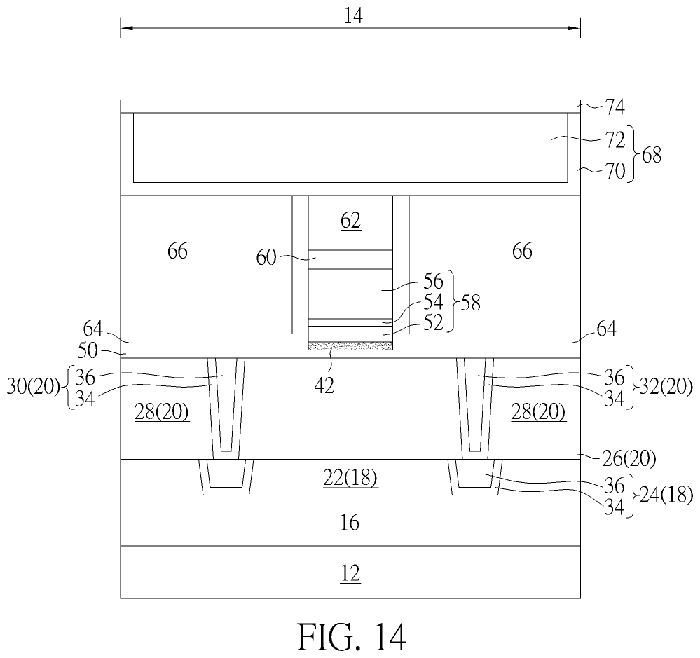

Next, as shown in FIG. 14, it would be desirable to repeat the steps (a) to (d) shown in FIGS. 10-13 n times for forming the structure shown in FIG. 14, in which n≥1. Specifically, it would be desirable to first conduct a series of etching processes starting from FIG. 10 by transforming the metallic byproduct 86 tin to an oxide byproduct 88, transforming the oxidized byproduct 88 into a damaged layer 90, removing the damaged layer 90, using low energy with high angle IBE process to trim sidewalls of the MTJ 58, and then repeating these four steps once or more than once such as two times, three times or even four times or more so that the sidewalls of the MTJ 58 are eventually shaped to form different slopes (not explicitly shown in FIG. 14).

Next, a cap layer 64 and an IMD layer 66 are formed on the MTJ 58, and one or more photo-etching process is conducted to remove part of the IMD layer 66 and part of the cap layer 64 to form at least a contact hole (not shown) exposing the hard mask 62. Next, conductive materials are deposited into the contact hole and a planarizing process such as CMP is conducted to form metal interconnection 68 connecting the hard mask 62 underneath, and another stop layer 74 is formed on the surface of the metal interconnection 68 thereafter. Similar to the aforementioned metal interconnections 24, the metal interconnection 68 could be embedded within the IMD layer 66 according to a single damascene process or dual damascene process. For instance, the metal interconnection 68 could further include a barrier layer 70 and a metal layer 72, in which the barrier layer 70 could be selected from the group consisting of titanium (Ti), titanium nitride (TiN), tantalum (Ta), and tantalum nitride (TaN) and the metal layer 72 could be selected from the group consisting of tungsten (W), copper (Cu), aluminum (Al), titanium aluminide (TiAl), and cobalt tungsten phosphide (CoWP).

In this embodiment, the IMD layer 66 preferably include an ultra low-k (ULK) dielectric layer including but not limited to for example porous material or silicon oxycarbide (SiOC) and the stop layer 74 preferably includes nitrogen doped carbide (NDC), silicon nitride (SiN), silicon carbon nitride (SiCN), or combination thereof and most preferably includes SiN. This completes the fabrication of a semiconductor device according to an embodiment of the present invention.

Referring again to FIG. 14, FIG. 14 further illustrates a structural view of a MRAM device according to an embodiment of the present invention. As shown in FIG. 14, the MRAM device includes an IMD layer 28 disposed on the substrate 12, metal interconnections 30, 32 in the IMD layer 28, a SOT layer 50 disposed on the metal interconnections 30, 32, an interface layer 42 disposed on the SOT layer 50, and a MTJ 58 disposed on the interface layer 42.

In contrast to the barrier layer 34 in the metal interconnections 30, 32 is extended to the surface of the IMD layer 28 as disclosed in the previous embodiment, the barrier layer 34 in the metal interconnections 30, 32 of this embodiment is disposed in the contact holes completely and the top surface of the barrier layer 34 is not higher than the top surface of the IMD layer 28 on two adjacent sides. In this embodiment, an interface layers 42 is disposed between the SOT layer 50 and the MTJ 58, in which the interface layer 42 could be made of a material of the SOT layer 50 underneath with nitride or oxide dopants. For instance, the interface layer 42 could include tungsten nitride (WN), platinum nitride (PtN), tungsten oxide (WO), or platinum oxide (PtO).

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a semiconductor device, comprising:
forming an inter-metal dielectric (IMD) layer on a substrate;
forming a contact hole in the IMD layer;
forming a barrier layer and a metal layer in the contact hole;
planarizing the metal layer;
forming a spin orbit torque (SOT) layer on the barrier layer and the metal layer; and
forming a magnetic tunneling junction (MTJ) on the SOT layer.

2. The method of claim 1, further comprising performing a doping process on the barrier layer and the metal layer.

3. The method of claim 2, wherein the doping process comprises nitrogen.

4. The method of claim 3, further comprising performing the doping process to form an interface layer on the metal layer.

5. The method of claim 4, wherein the interface layer comprises tungsten nitride (WN).

6. The method of claim 1, wherein the barrier layer comprises titanium nitride (TiN).

7. A semiconductor device, comprising:
an inter-metal dielectric (IMD) layer on a substrate;
a metal interconnection in the IMD layer, wherein the metal interconnection comprises:
a barrier layer in the IMD layer and extended to a surface of the IMD layer; and
a metal layer on the barrier layer;
a spin orbit torque (SOT) layer on the barrier layer and the metal layer; and
a magnetic tunneling junction (MTJ) on the SOT layer.

8. The semiconductor device of claim 7, further comprising an interface layer on the metal layer.

9. The semiconductor device of claim 8, wherein the interface layer comprises tungsten nitride (WN).

10. The semiconductor device of claim 8, wherein top surfaces of the interface layer and the barrier layer are coplanar.

11. The semiconductor device of claim 7, wherein the barrier layer comprises titanium nitride (TiN).

12. The semiconductor device of claim 7, wherein a top surface of the barrier layer is higher than a top surface of the IMD layer.

13. A semiconductor device, comprising:
an inter-metal dielectric (IMD) layer on a substrate;
a metal interconnection in the IMD layer;
a spin orbit torque (SOT) layer on the metal interconnection;
an interface layer on the SOT layer; and
a magnetic tunneling junction (MTJ) on the interface layer.

14. The semiconductor device of claim 13, wherein the interface layer comprises metal nitride.

15. The semiconductor device of claim 13, wherein the interface layer comprises metal oxide.

16. The semiconductor device of claim 13, wherein a width of the interface layer is less than a width of the SOT layer.

17. The semiconductor device of claim 13, wherein a sidewall of the MTJ is aligned with a sidewall of the interface layer.
